(19) United States
(12) Patent Application Publication
(10) Pub. No.: US 2026/0018221 A1
(43) Pub. Date: Jan. 15, 2026

(54) UNIFORM RANDOMNESS FOR PROGRAM-ERASE CYCLES USING MULTI-BIT INVERSION SEEDS

(71) Applicant: SK hynix Inc., Icheon-si (KR)

(72) Inventors: Pengfei Huang, San Jose, CA (US); Fan Zhang, Fremont, CA (US)

(21) Appl. No.: 18/773,314

(22) Filed: Jul. 15, 2024

(51) Int. Cl. G11C 16/34; G11C 16/10; G11C 29/52

(52) U.S. Cl. CPC G11C 16/349; G11C 16/102; G11C 29/52

(57) ABSTRACT

Devices, systems, and methods for improving performance of a non-volatile memory are described. An example method includes generating, based on a number of program erase cycles of the non-volatile memory, an inversion seed for a page type of the non-volatile memory, and then generating a circular shift flip sequence based on the inversion seed and a flip sequence. The method further includes performing a bit-flipping operation on an input bit sequence based on the circular shift flip sequence to generate an intermediate bit sequence, processing the intermediate bit sequence to generate an output bit sequence, and finally, writing the output bit sequence to a page in the non-volatile memory. In this example, the page that the output bit sequence is written (or programmed) to is of the page type for which the inversion seed and circular shift flip sequence are generated.

### TECHNICAL FIELD

This patent document generally relates to non-volatile memory devices, and more specifically, to preventing uneven and accelerated wear out in non-volatile memory devices.

### BACKGROUND

Wearing out in NAND memory devices refers to the gradual degradation of the memory cells over time due to repeated program and erase cycles (PECs). NAND flash memory, commonly used in solid-state drives (SSDs) and USB drives, has a finite lifespan and can only endure a certain number of write and erase operations before it starts to wear out. Each time data is written or erased in a NAND memory cell, it causes stress on the floating gate, which stores the charge representing the data. Over time, this stress can lead to electron trapping and leakage, resulting in a decrease in the cell's ability to retain charge accurately. As a result, the memory cell becomes less reliable, leading to potential data corruption or loss.

To mitigate wearing out, NAND memory devices employ various techniques such as wear leveling and error correction codes. Wear leveling distributes write and erase operations evenly across all memory cells, preventing specific cells from wearing out faster than others. Error correction codes help detect and correct errors that may occur due to cell wear.

### SUMMARY

Embodiments of the disclosed technology relate to methods, systems, and devices that improve performance of non-volatile memory. In some examples, the performance of the non-volatile memory device is improved by implementing uniform randomness to ensure level wearing when writing data to the non-volatile memory, and wherein the uniform randomness is implemented for each program-erase cycle (PEC) using a multi-bit inversion seed, This increases the useful lifespan of the non-volatile memory.

In one example, a method for improving performance of a memory device is described. The method includes generating, based on a number of program erase cycles of the non-volatile memory, an inversion seed for a page type of the non-volatile memory, and then generating a circular shift flip sequence based on the inversion seed and a flip sequence. The method further includes performing a bit-flipping operation on an input bit sequence based on the circular shift flip sequence to generate an intermediate bit sequence, processing the intermediate bit sequence to generate an output bit sequence, and finally, writing the output bit sequence to a page in the non-volatile memory. In this example, the page that the output bit sequence is written to is of the page type for which the inversion seed and circular shift flip sequence are generated.

In another example, the methods may be embodied in the form of an apparatus that includes a processor and a memory coupled to the processor.

In yet another example, the methods may be embodied in the form of processor-executable instructions and stored on a computer-readable program medium.

The subject matter described in this patent document can be implemented in specific ways that provide one or more of the following features.

### BRIEF DESCRIPTION OF THE DRAWINGS

FIG. 1 illustrates an example of a memory system.

FIG. 2 is an illustration of an example non-volatile memory device.

FIG. 3 is an example diagram illustrating the cell voltage level distribution (Vₜₕ) of a non-volatile memory device.

FIG. 4 is another example diagram illustrating the cell voltage level distribution (Vₜₕ) of a non-volatile memory device.

FIG. 5 is an example diagram illustrating the cell voltage level distribution (Vₜₕ) of a non-volatile memory device before and after program interference.

FIG. 6 is an example diagram illustrating the cell voltage level distribution (Vₜₕ) of a non-volatile memory device as a function of the reference voltage.

FIG. 7A is an example block diagram of an encoder-randomizer-NAND (ERN) architecture for a non-volatile memory device.

FIG. 7B is an example block diagram of a randomizer-encoder-NAND (REN) architecture for a non-volatile memory device.

FIG. 8 is an example data flow when using a multi-bit inversion seed to write user data to a non-volatile memory device with the ERN architecture.

FIG. 9 is an example of using the circular shift flip sequence when writing user data to a non-volatile memory device.

FIG. 10 is an example NAND cell state transition matrix for a previous program-erase cycle (PEC) to a current PEC.

FIG. 11 illustrates a flowchart of an example method for improving the performance of a memory device.

FIG. 12 is an example diagram illustrating a storage device that can be configured to implement the described embodiments.

### DETAILED DESCRIPTION

Semiconductor memory devices may be volatile or non-volatile. The volatile semiconductor memory devices perform read and write operations at high speeds, while contents stored therein may be lost at power-off. The non-volatile semiconductor memory devices may retain contents stored therein even at power-off. The non-volatile semiconductor memory devices may be used to store contents, which must be retained regardless of whether they are powered.

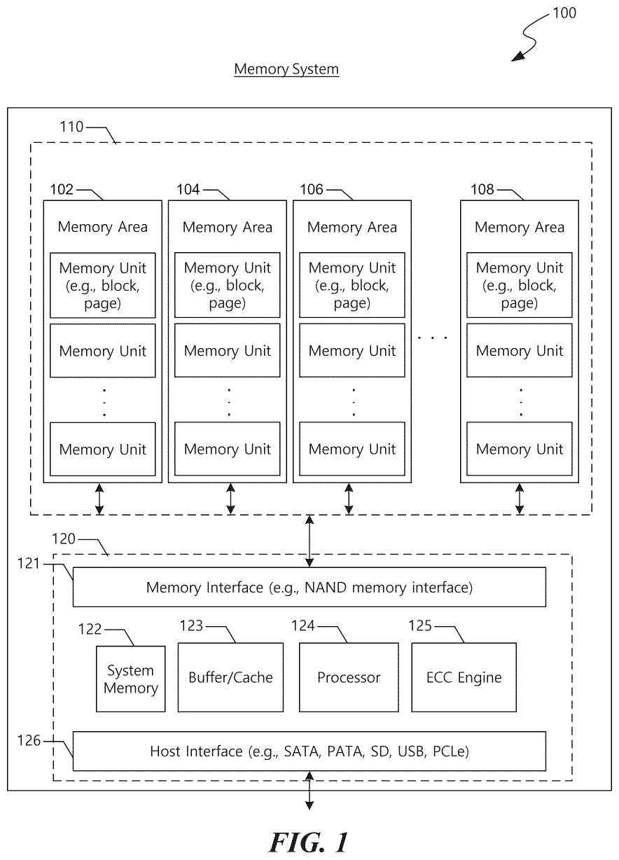

FIGS. 1-6 overview a non-volatile memory system (e.g., a flash-based memory, NAND flash) in which embodiments of the disclosed technology may be implemented.

FIG. 1 is a block diagram of an example of a memory system 100 implemented based on some embodiments of the disclosed technology. The memory system 100 includes a memory module 110 that can be used to store information for use by other electronic devices or systems. The memory system 100 can be incorporated (e.g., located on a circuit board) in other electronic devices and systems. Alternatively, the memory system 100 can be implemented as an external storage device such as a USB flash drive and a solid-state drive (SSD).

The memory module 110 included in the memory system 100 can include memory areas (e.g., memory arrays) 102, 104, 106, and 108. Each of the memory areas 102, 104, 106, and 108 can be included in a single memory die or in multiple memory dice. The memory die can be included in an integrated circuit (IC) chip.

Each of the memory areas 102, 104, 106, and 108 includes a plurality of memory cells. Read, program, or erase operations can be performed on a memory unit basis. Thus, each memory unit can include a predetermined number of memory cells. The memory cells in a memory area 102, 104, 106, and 108 can be included in a single memory die or in multiple memory dice.

The memory cells in each of memory areas 102, 104, 106, and 108 can be arranged in rows and columns in the memory units. Each of the memory units can be a physical unit. For example, a group of a plurality of memory cells can form a memory unit. Each of the memory units can also be a logical unit. For example, the memory unit can be a block or a page that can be identified by a unique address such as a block address or a page address, respectively. For another example, wherein the memory areas 102, 104, 106, and 108 can include computer memories that include memory banks as a logical unit of data storage, the memory unit can be a bank that can be identified by a bank address. During a read or write operation, the unique address associated with a particular memory unit can be used to access that particular memory unit. Based on the unique address, information can be written to or retrieved from one or more memory cells in that particular memory unit.

The memory cells in the memory areas 102, 104, 106, and 108 can include non-volatile memory cells. Examples of non-volatile memory cells include flash memory cells, phase change random-access memory (PRAM) cells, magnetoresistive random-access memory (MRAM) cells, or other types of non-volatile memory cells. In an example implementation where the memory cells are configured as NAND flash memory cells, the read or write operation can be performed on a page basis. However, an erase operation in a NAND flash memory is performed on a block basis.

Each of the non-volatile memory cells can be configured as a single-level cell (SLC) or multiple-level memory cell. A single-level cell can store one bit of information per cell. A multiple-level memory cell can store more than one bit of information per cell. For example, each of the memory cells in the memory areas 102, 104, 106, and 108 can be configured as a multi-level cell (MLC) to store two bits of information per cell, a triple-level cell (TLC) to store three bits of information per cell, or a quad-level cells (QLC) to store four bits of information per cell. In another example, each of the memory cells in memory area 102, 104, 106, and 108 can be configured to store at least one bit of information (e.g., one bit of information or multiple bits of information), and each of the memory cells in memory area 102, 104, 106, and 108 can be configured to store more than one bit of information.

As shown in FIG. 1, the memory system 100 includes a controller module 120. The controller module 120 includes a memory interface 121 to communicate with the memory module 110, a host interface 126 to communicate with a host (not shown), a processor 124 to execute firmware-level code, and caches and memories 123 and 122, respectively to temporarily or persistently store executable firmware/instructions and associated information. In some implementations, the controller unit 120 can include an error correction engine 125 to perform error correction operation on information stored in the memory module 110. Error correction engine 125 can be configured to detect/correct single bit error or multiple bit errors. In another implementation, error correction engine 125 can be located in the memory module 110.

The host can be a device or a system that includes one or more processors that operate to retrieve data from the memory system 100 or store or write data into the memory system 100. In some implementations, examples of the host can include a personal computer (PC), a portable digital device, a digital camera, a digital multimedia player, a television, and a wireless communication device.

In some implementations, the controller module 120 can also include a host interface 126 to communicate with the host. Host interface 126 can include components that comply with at least one of host interface specifications, including but not limited to, Serial Advanced Technology Attachment (SATA), Serial Attached Small Computer System Interface (SAS) specification, Peripheral Component Interconnect Express (PCIe).

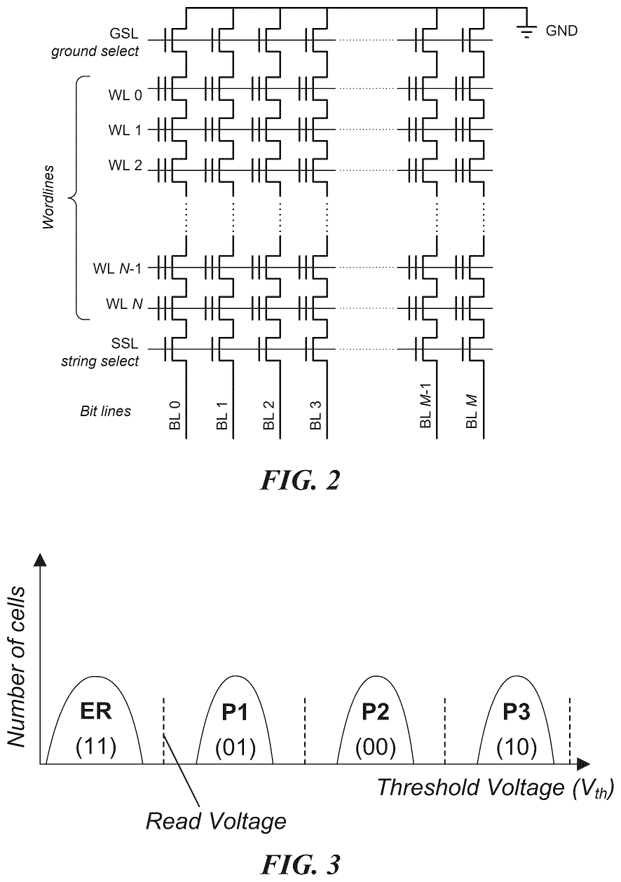

FIG. 2 illustrates an example of a memory cell array implemented based on some embodiments of the disclosed technology.

In some implementations, the memory cell array can include NAND flash memory array that is partitioned into many blocks, and each block contains a certain number of pages. Each block includes a plurality of memory cell strings, and each memory cell string includes a plurality of memory cells.

In some implementations where the memory cell array is NAND flash memory array, read and write (program) operations are performed on a page basis, and erase operations are performed on a block basis. All the memory cells within the same block must be erased at the same time before performing a program operation on any page included in the block. In an implementation, NAND flash memories may use an even/odd bit-line structure. In another implementation, NAND flash memories may use an all-bit-line structure. In the even/odd bit-line structure, even and odd bit-lines are interleaved along each word-line and are alternatively accessed so that each pair of even and odd bit-lines can share peripheral circuits such as page buffers. In all-bit-line structure, all the bit-lines are accessed at the same time.

FIG. 3 illustrates an example of threshold voltage distribution curves in a multi-level cell device, wherein the number of cells for each program/erase state is plotted as a function of the threshold voltage. As illustrated therein, the threshold voltage distribution curves include the erase state (denoted “ER” and corresponding to “11”) with the lowest threshold voltage, and three program states (denoted “P1”, “P2” and “P3” corresponding to “01”, “00” and “10”, respectively) with read voltages in between the states (denoted by the dotted lines). In some embodiments, each of the threshold voltage distributions of program/erase states has a finite width because of differences in material properties across the memory array.

Although FIG. 3 shows a multi-level cell device by way of example, each of the memory cells can be configured to store any number of bits per cell. In some implementations, each of the memory cells can be configured as a single-level cell (SLC) to store one bit of information per cell, or as a triple-level cell (TLC) to store three bits of information per cell, or as a quad-level cells (QLC) to store four bits of information per cell.

In writing more than one data bit in a memory cell, fine placement of the threshold voltage levels of memory cells is needed because of the reduced distance between adjacent distributions. This is achieved by using incremental step pulse program (ISPP), i.e., memory cells on the same word-line are repeatedly programmed using a program-and-verify approach with a staircase program voltage applied to word-lines. Each programmed state associates with a verify voltage that is used in verify operations and sets the target position of each threshold voltage distribution window.

Read errors can be caused by distorted or overlapped threshold voltage distribution. An ideal memory cell threshold voltage distribution can be significantly distorted or overlapped due to, e.g., program and erase (P/E) cycle, cell-to-cell interference, and data retention errors, which will be discussed in the following, and such read errors may be managed in most situations by using error correction codes (ECCO).

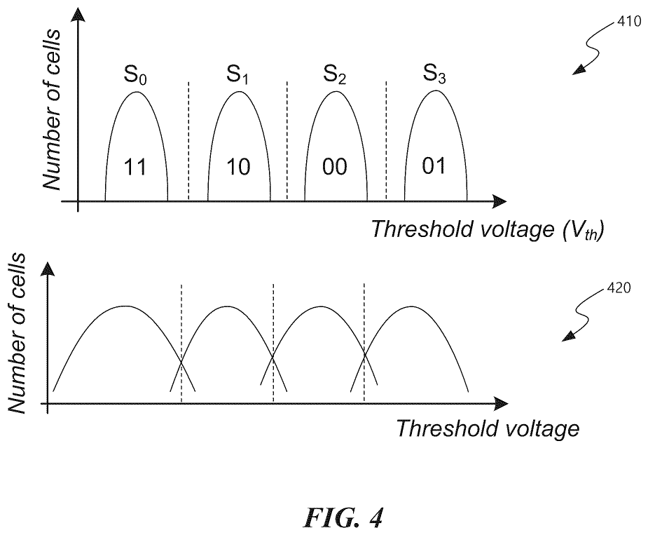

FIG. 4 illustrates an example of ideal threshold voltage distribution curves 410 and an example of distorted threshold voltage distribution curves 420. The vertical axis indicates the number of memory cells that has a particular threshold voltage represented on the horizontal axis.

For n-bit multi-level cell NAND flash memory, the threshold voltage of each cell can be programmed to 2ⁿ possible values. In an ideal multi-level cell NAND flash memory, each value corresponds to a non-overlapping threshold voltage window.

Flash memory P/E cycling causes damage to a tunnel oxide of floating gate of a charge trapping layer of cell transistors, which results in threshold voltage shift and thus gradually degrades memory device noise margin. As P/E cycles increase, the margin between neighboring distributions of different programmed states decreases and eventually the distributions start overlapping. The data bit stored in a memory cell with a threshold voltage programmed in the overlapping range of the neighboring distributions may be misjudged as a value other than the original targeted value.

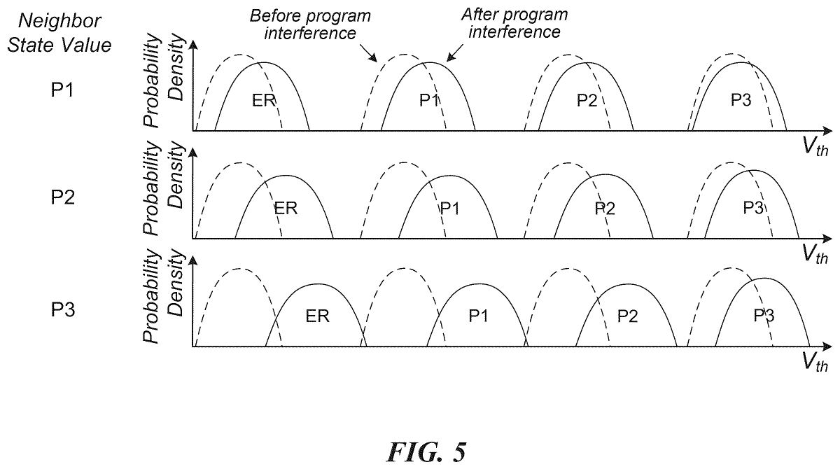

FIG. 5 illustrates an example of a cell-to-cell interference in NAND flash memory. The cell-to-cell interference can also cause threshold voltages of flash cells to be distorted. The threshold voltage shift of one memory cell transistor can influence the threshold voltage of its adjacent memory cell transistor through parasitic capacitance-coupling effect between the interfering cell and the victim cell. The amount of the cell-to-cell interference may be affected by NAND flash memory bit-line structure. In the even/odd bit-line structure, memory cells on one word-line are alternatively connected to even and odd bit-lines and even cells are programmed ahead of odd cells in the same word-line. Therefore, even cells and odd cells experience different amount of cell-to-cell interference. Cells in all-bit-line structure suffer less cell-to-cell interference than even cells in the even/odd bit-line structure, and the all-bit-line structure can effectively support high-speed current sensing to improve the memory read and verify speed.

The dotted lines in FIG. 5 denote the nominal distributions of P/E states (before program interference) of the cells under consideration, and the “neighbor state value” denotes the value that the neighboring state has been programmed to. As illustrated in FIG. 5, if the neighboring state is programmed to P1, the threshold voltage distributions of the cells under consideration shift by a specific amount. However, if the neighboring state is programmed to P2, which has a higher threshold voltage than P1, that results in a greater shift compared to the neighboring state being P1. Similarly, the shift in the threshold voltage distributions is greatest when the neighboring state is programmed to P3.

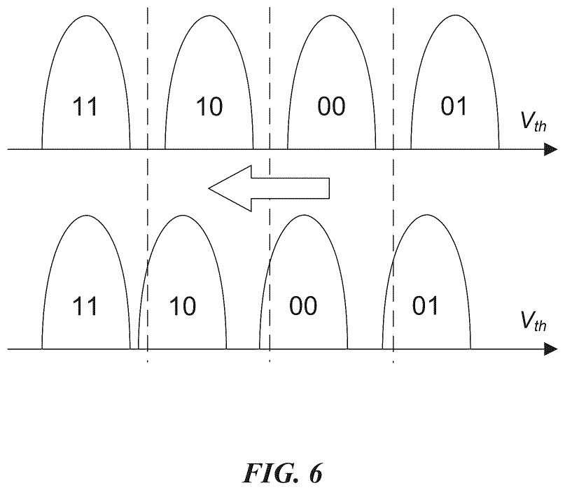

FIG. 6 illustrates an example of a retention error in NAND flash memory by comparing normal threshold-voltage distribution and shifted threshold-voltage distribution. The data stored in NAND flash memories tend to get corrupted over time and this is known as a data retention error. Retention errors are caused by loss of charge stored in the floating gate or charge trap layer of the cell transistor. Due to wear of the floating gate or charge trap layer, memory cells with more program erase cycles are more likely to experience retention errors. In the example of FIG. 6, comparing the top row of voltage distributions (before corruption) and the bottom row of distributions (contaminated by retention error) reveals a shift to the left.

In NAND-based storage systems (e.g., the examples illustrated in FIGS. 1-6) and solid-state drive (SSD) applications, writing identical data patterns on the NAND device leads to an acceleration in the wearing out of the NAND device. To mitigate this adverse effect, the SSD controller of an SSD is required to determine that the host system keeps writing the same data and then artificially change the data pattern that is written to prevent acceleration of the NAND device wear-out. This is frequently achieved by the System-on-Chip (SoC), which typically has access to Advanced Encryption Standard (AES) functions, that randomizes the host data, thereby supporting the data pattern change function. However, certain memory device implementations, applications, or systems, do not support AES functions, and in those cases, it is difficult for the firmware to guarantee that the firmware metadata (e.g., firmware configuration metadata) has been properly randomized.

Current implementations for randomizing user data, using error correction code (ECC) encoders/decoders and randomizers, but without access to AES functions, include using an inversion seed-based scheme that has the following write and read operations.

### Write Operation

1. The firmware determines the number of program-erase cycles (PECs) and adds a single bit that is termed the inversion seed for metadata.
2. The SoC inverts (or flips) the data when the inversion seed indicates the “flip” operation should be performed, e.g., “1” for flip, “0” for not flip (or vice versa)
3. Subsequent to the conditional inversion, the controller of the memory device ECC-encodes the data, scrambles the data, and programs (or writes) the data on the NAND.

### Read Operation

1. The controller of the memory device reads back the stored data from the NAND, descrambles the data, ECC-decodes the data.
2. The SoC inverts (or flips) the data based on the value of the inversion seed. In these existing implementations, the seed generation step (Step 1) of the write operation directly uses the lower bits of the PEC value, which causes non-uniform NAND cell state transitions when determined over multiple PECs, and results in a shallow erase issue. The non-uniformity of the NAND cell state transitions is equivalent to only a specific subset of cells being targeted for erasure. This leads to a mix of programmed and erased cells within a block of the memory device, thereby resulting in fragmentation, an increased failed bit count (FBC) of the erase state, and greater susceptibility to read disturb errors and program disturb errors.

Embodiments of the disclosed technology mitigate the aforementioned issues by achieving a uniform NAND cell state transition for every program-erase cycle (PEC), which is the optimal solution for a random algorithm. In some examples, a 6-bit inversion seed is generated in firmware, and data inversion (or bit flipping) is implemented in the SoC. In some examples, a 6-bit inversion seed is designed for each triple-level cell (TLC) NAND page type, e.g., a most significant bit (MSB) page type, a center significant bit (CSB) page type, or a least significant bit (LSB) page type. In some examples, the inversion seed is embedded into the firmware metadata. The described embodiments also provide a flip sequence designed for each page type, and subsequently, the data from each page is randomized using the inversion seed and flip sequence for the page type of that page. The SoC implements the inversion operation (or bit-flipping), which results in a particularly fast implementation. Simulation results, which are included in this document, illustrate the efficacy of the described embodiments in generating a uniform NAND cell state transition matrix for each PEC.

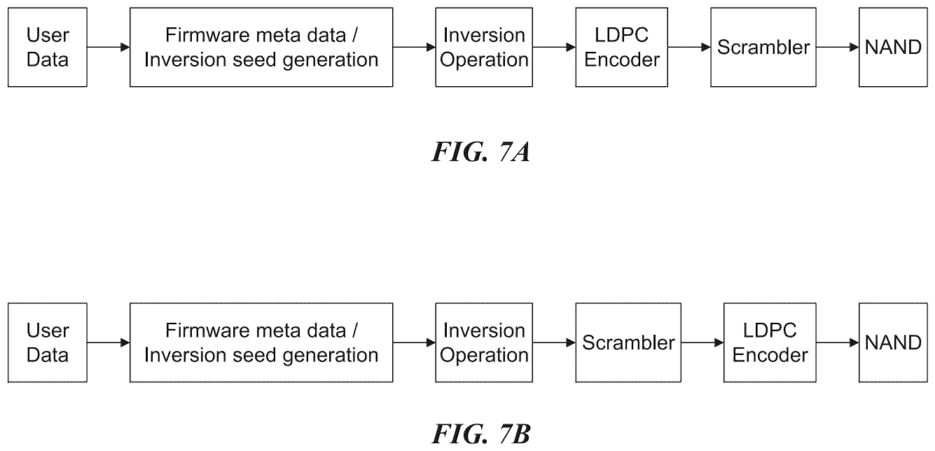

The described embodiments can be implemented in different non-volatile memory architectures. In some examples, the described techniques are performed in an encoder-randomizer-NAND (ERN) architecture, shown in FIG. 7A. Therein, the user data and firmware metadata (which includes the inversion seed) are successively processed by an inversion operation, an ECC encoder, and a scrambler, before being written to the NAND device. In other examples, the described techniques are performed in a randomizer-encoder-NAND (REN) architecture, shown in FIG. 7B. Therein, the user data and firmware metadata (which includes the inversion seed) are successively processed by the inversion operation, the scrambler, and the ECC encoder, before being written to the NAND device. In the example architectures shown in FIGS. 7A and 7B, the ECC encoder can be implemented using a low-density parity check (LDPC) encoder. More generally, the ECC encoder includes repeating and distributing the input data bits to multiple constituent encoders (e.g., accumulators), and the ECC decoder includes using iterative decoding techniques that operate on soft decision information.

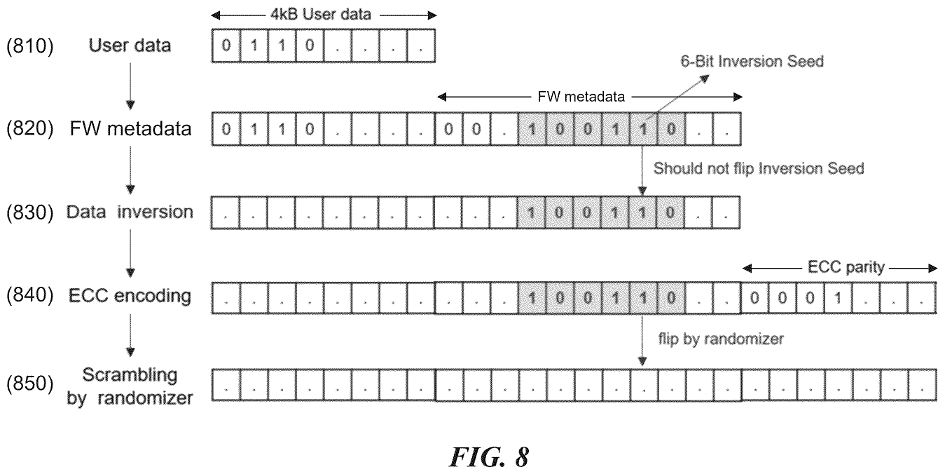

FIG. 8 shows an example data flow when using the ERN architecture for a page in a triple-level cell (TLC) NAND. As shown therein, the user data (e.g., 4 kB) is received (810) and concatenated with the firmware metadata (820), which includes the 6-bit inversion seed. In the data inversion operation (830), the SoC performs the inversion operation on the input bits except for the 6-bit inversion seed. In some examples, the SoC performs the inversion operation based on the flip sequence and 6-bit inversion seed for the particular page type of this page. The inversion operation (830) is followed by the ECC-encoding operation (840) and the scrambling operation (850) that is implemented by the randomizer.

In some embodiments, the firmware of the memory device (which is typically stored in a non-volatile memory of the memory device) generates an N-bit inversion seed (with N being an integer greater than or equal to two) for each page type of a K-level NAND device (that stores K bits per physical cell) of the memory device. For example, in a triple-level cell (TLC) NAND (with K=3) that stores three data bits in each physical cell, the LSB (Least Significant Bit), CSB (Central Significant Bit) and MSB (Most Significant Bit) exhibit very different program latencies. Because of the very different program latencies, the TLC SSD design separates these bits into three types of pages with diverse program latencies, i.e., LSB pages, CSB pages, and MSB pages. In an example implementation, the LSB page has the shortest program latency (e.g., 500 μs), a CSB page has medium program latency (e.g., 2000 μs), and an MSB page has the longest program latency (e.g., 5500 μs). Due to the high program latencies of CSB and MSB pages, write requests served with CSB and MSB pages usually have much longer response times than with LSB pages (up to 10×).

To provide improved performance that accounts for the diverse program latencies of the different page types, embodiments of the disclosed technology provide a multi-bit inversion seed and flip sequence for each page type, e.g., a separate 6-bit inversion seed is provided for each type of MSB pages, CSB pages, and LSB pages in a TLC NAND device.

In an example, the N-bit inversion seed for a K-level NAND is determined based on an index (IDX) that is calculated based on a number of program-erase cycles (PEC), e.g.,
IDX=PEC % 2^{N}, where % is the modulo operation,
PageType_k_Inversion_Seed=IDX, k=1, 2, . . . , K.

Alternatively, the index (IDX) used to derive the inversion seed can be calculated based on PEC using the following expression:
IDX=(PEC+PA) % 2^{N}, where PA is the NAND page Physical Address.

In some examples, a separate 6-bit inversion seed is defined for the three page types of a triple-level cell (TLC) NAND, e.g., MSB page, CSB page, and LSB page as follows:

$$IDX = PEC \% 64 ,$$

$$MSB\_Inversion \_Seed = IDX ,$$

$$CSB\_Inversion \_Seed = IDX ,$$

$$LSB\_Inversion \_Seed = IDX .$$

In this example, for PEC=2, MSB_Inversion_Seed=000010, CSB_Inversion_Seed=000010, and LSB_Inversion_Seed=000010. In other examples, the inversion seeds for each of the types of pages can be configured with different values. In yet other examples, the inversion seeds for two (but not all three) types of pages can be configured with the same value.

In other examples, a 4-bit inversion seed is better suited for a multi-level cell (MLC) that includes an MSB page and an LSB page. In yet other examples, an 8-bit inversion seed is better suited for a quad-level cell (QLC) that includes four pages that are denoted page 1 (the MSB page), page 2, page 3, and page 4 (the LSB page). In yet other examples, a 10-bit inversion seed is better suited for a penta-level cell (PLC) that includes five pages that are denoted page 1 (the MSB page), page 2, page 3, page 4, and page 5 (the LSB page).

In some embodiments, when a separate N-bit inversion seed is provided for each page type of a K-level cell, a separate 2^{N}-bit flip sequence, denoted PageType_k_FS[0 (2^{N}−1)], can be determined for each page type. In an example, these flip sequences can be determined using the following procedure:

For a sequence denoted X₀, X₁, X₂, . . . , X₂_{^{N}}₋₁, X₂_{^{N}}, where each element belongs to the set {0, 1, 2, . . . , 2^{K}−1}, an associated matrix P is determined as follows:
1. Initialize P[i, j] for i∈{0,1, . . . , 2^{K}−1} and j∈{0,1, . . . , 2^{K}−1}.
2. Accumulate P[i, j] as follows:

for k = 0, 1, ..., (2^{N} − 1)
P[Xₖ, Xₖ₊₁] = P[Xₖ, Xₖ₊₁] + 1
end

The sequence X₀, X₁, X₂, . . . , X₂_{^{N}}₋₁, X₂_{^{N}} is determined such that:

$$P [ i , j ] = 1 for i ∈ \{ 0 , 1 , … , {2}^{K} - 1 \} and j ∈ \{ 0 , 1 , … , {2}^{K} - 1 \} .$$

Then, the sequence is used to construct a table of size 2^{N}×K, where the n-th row (n=1, 2, . . . , 2^{N}, and corresponding to row index 0, 1, 2, . . . , 2^{N}−1, respectively) of the table is Xₙ expressed in binary using K bits, and the k-th column is the 2^{N}-bit flip sequence for page k of the K-level NAND, which is denoted PageType_k_FS[0:2^{N}−1].

An example output for this flip sequence generation procedure is shown for N=6 and K=3, i.e., a 64-bit flip sequence is determined for each page type (MSB, CSB, LSB) of a TLC NAND device, and denoted as MSB_FS[0:63], CSB_FS[0:63], and LSB_FS[0:63], respectively. The 64×3 table that is formed from the sequence X₀, X₁, X₂, . . . , X₆₃, X₆₄ is shown below.

TABLE 1
Flip sequence for each page type of a TLC NAND

| idx | MSB_FS | CSB_FS | LSB_FS |
|---|---|---|---|
| 0 | 1 | 1 | 1 |
| 1 | 1 | 1 | 1 |
| 2 | 1 | 1 | 0 |
| 3 | 1 | 1 | 1 |
| 4 | 1 | 0 | 1 |
| 5 | 1 | 1 | 1 |
| 6 | 1 | 0 | 0 |
| 7 | 1 | 1 | 1 |
| 8 | 0 | 1 | 1 |
| 9 | 1 | 1 | 1 |
| 10 | 0 | 1 | 0 |
| 11 | 1 | 1 | 1 |
| 12 | 0 | 0 | 1 |
| 13 | 1 | 1 | 1 |
| 14 | 0 | 0 | 0 |
| 15 | 1 | 1 | 0 |
| 16 | 1 | 1 | 0 |
| 17 | 1 | 0 | 1 |
| 18 | 1 | 1 | 0 |
| 19 | 1 | 0 | 0 |
| 20 | 1 | 1 | 0 |
| 21 | 0 | 1 | 1 |
| 22 | 1 | 1 | 0 |
| 23 | 0 | 1 | 0 |
| 24 | 1 | 1 | 0 |
| 25 | 0 | 0 | 1 |
| 26 | 1 | 1 | 0 |
| 27 | 0 | 0 | 0 |
| 28 | 1 | 0 | 1 |
| 29 | 1 | 0 | 1 |
| 30 | 1 | 0 | 0 |
| 31 | 1 | 0 | 1 |
| 32 | 0 | 1 | 1 |
| 33 | 1 | 0 | 1 |
| 34 | 0 | 1 | 0 |
| 35 | 1 | 0 | 1 |
| 36 | 0 | 0 | 1 |
| 37 | 1 | 0 | 1 |
| 38 | 0 | 0 | 0 |
| 39 | 1 | 0 | 0 |
| 40 | 1 | 0 | 0 |
| 41 | 0 | 1 | 1 |
| 42 | 1 | 0 | 0 |
| 43 | 0 | 1 | 0 |
| 44 | 1 | 0 | 0 |
| 45 | 0 | 0 | 1 |
| 46 | 1 | 0 | 0 |
| 47 | 0 | 0 | 0 |
| 48 | 0 | 1 | 1 |
| 49 | 0 | 1 | 1 |
| 50 | 0 | 1 | 0 |
| 51 | 0 | 1 | 1 |
| 52 | 0 | 0 | 1 |
| 53 | 0 | 1 | 1 |
| 54 | 0 | 0 | 0 |
| 55 | 0 | 1 | 0 |
| 56 | 0 | 1 | 0 |
| 57 | 0 | 0 | 1 |
| 58 | 0 | 1 | 0 |
| 59 | 0 | 0 | 0 |
| 60 | 0 | 0 | 1 |
| 61 | 0 | 0 | 1 |
| 62 | 0 | 0 | 0 |
| 63 | 0 | 0 | 0 |

In some embodiments, the data inversion operation is implemented in hardware by the SoC, and is therefore much faster than a software implementation. The data inversion operation includes (at Step (1)) generating, for each page type, a circularly shifted 2^{N}-bit flip sequence (denoted PageType_k_FS_CS[0:2^{N}−1]) based on the N-bit inversion seed and the 2^{N}-bit flip sequence for that page type, and (at Step (2)) using the circularly shifted 2^{N}-bit flip sequence to perform the inversion operation on the input user data. For example, the circularly shifted 2^{N}-bit flip sequence is determined as:

```
PageType_k_FS_CS[0:2^{N}−1]
  = ( PageType_k_FS[2^{N} − PageType_k_Inversion_Seed : 2^{N} − 1],
    PageType_k_FS[0 : 2^{N} − 1 − PageType_k_Inversion_Seed] ).
```

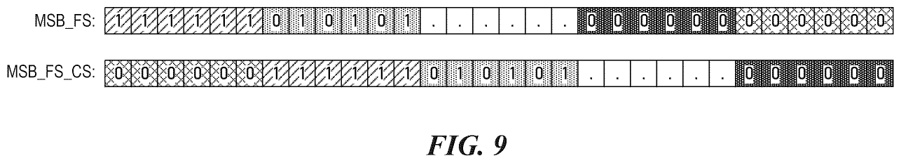

In the example of the TLC NAND device and Table 1 above, MSB_FS=111111| . . . |000000|000000, and when MSB_Inversion_Seed=6, the resulting circularly shifted flip sequence is MSB_FS_CS=000000|111111| . . . |000000, as shown in FIG. 9.

Once the circularly shifted flip sequence for the page type has been determined, the input data sequence is the concatenated user data and firmware metadata (that includes the N-bit inversion seed). Let PageType_k_X [0:n] represent the input data sequence, where n=2^{N}×p−1 and represents p sections of 2^{N} bits each. Furthermore, location indices of the N-bit inversion seed are denoted IS_LOC, and the data inversion output is denoted PageType_k_Y[0:n], which is determined as follows:

```
for q = 0, 1, ..., p−1
  PageType_k_Y[0 + 2^{N}×q : (2^{N}−1) + 2^{N}×q] =
    XOR( PageType_k_X[0 + 2^{N}×q : (2^{N}−1) +
    2^{N}×q], PageType_k_FS_CS )
  PageType_k_Y[IS_LOC] = PageType_k_X[IS_LOC]
```

It is noted that the second operation above does not apply the XOR operation to bits that correspond to the N-bit inversion seed in the firmware metadata, e.g., as shown in FIG. 8.

For the TLC NAND device example, the data inversion output is determined as:

```
for q = 0, 1, ..., p−1
  MSB_Y[64×q : 63+64×q] = XOR(
  MSB_X[64×q : 63+64×q], MSB_FS_CS )
  MSB_Y[IS_LOC] = MSB_X[IS_LOC]
  CSB_Y[64×q : 63+64×q] = XOR(
  CSB_X[64×q : 63+64×q], CSB_FS_CS )
  CSB_Y[IS_LOC] = CSB_X[IS_LOC]
  LSB_Y[64×q : 63+64×q] = XOR(
  LSB_X[64×q : 63+64×q], LSB_FS_CS )
  LSB_Y[IS_LOC] = LSB_X[IS_LOC]
```

In some embodiments, the read operation from the NAND device is implemented as a set of inverse operations corresponding to the steps described above. The value of PageType_k_Inversion_Seed is used to determine the value of IDX, which is used to generate the circular shift flip sequences PageType_k_FS_CS, which was used in Step (1) of the data inversion operation. Then, for each page type, the XOR function is computed between the circular shift flip sequences PageType_k_FS_CS and the output PageType_k_Y to obtain the input PageType_k_X, except for the bits corresponds to the location indices of the inversion seed. In the example of the TLC NAND device, the 6-bit inversion seed is used to sequentially determine IDX, the circular shift flip sequences (MSB_FS_CS, CSB_FS_CS and LSB_FS_CS), and given the outputs (MSB_Y, CSB_Y and LSB_Y), the inputs (MSB_X, CSB_X and LSB_X) can be determined (except for the inversion seed bit locations).

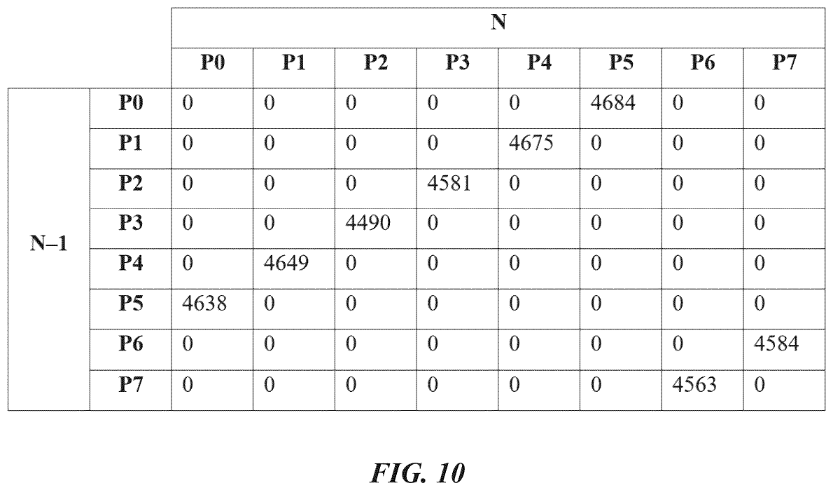

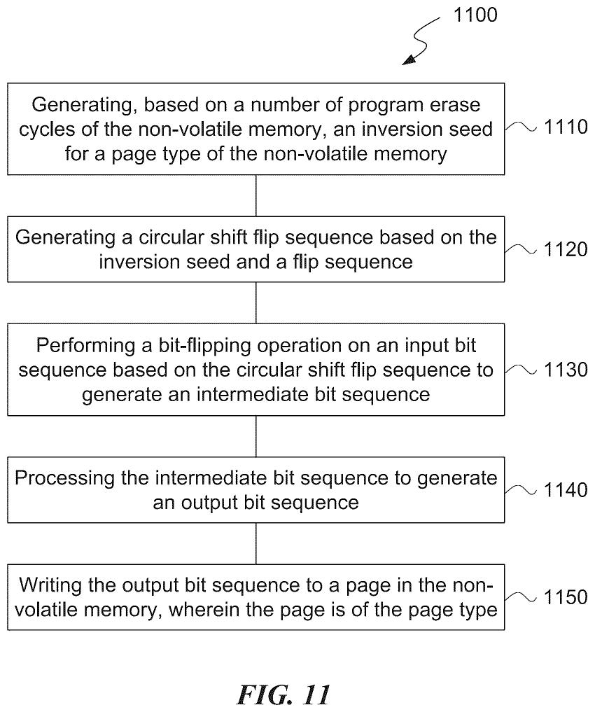

The efficacy of the disclosed technology is evidenced through simulation results. For example, in a TLC NAND with eight states (denoted P0, P1, . . . , P7), the cell state transitions from a previous erase and program operation to a current erase and program operation can be represented using an 8×8 cell state transition matrix. An example of the cell state transition matrix for a TLC NAND is shown in FIG. 10. An element therein corresponds to the number of states that move from an (N−1)-th PEC to an N-th PEC, and as shown in FIG. 10, 4684 cells with state P0 are moved to state P5, 4675 cells with state P1 are moved to state P4, and so on.

As an example, the case of one wordline (WL) with 4608 B bit lines is considered. It is assumed that the MSB, CSB, and LSB data (e.g., received from the host) has length 4608 B and satisfies a binomial distribution with p=0.5, and are fixed over all PECs. Applying the 6-bit inversion seed, and the methods described above, a fairly uniform cell state transition matrix is obtained for every PEC.

For example, for the first PEC, the 8×8 cell state transition matrix is given by the following:

$$[ \begin{matrix}572 & 556 & 572 & 580 & 565 & 629 & 570 & 577 \\ 594 & 575 & 559 & 585 & 561 & 550 & 587 & 592 \\ 562 & 603 & 592 & 564 & 570 & 567 & 565 & 593 \\ 601 & 594 & 541 & 626 & 563 & 585 & 560 & 624 \\ 580 & 569 & 605 & 542 & 575 & 603 & 569 & 580 \\ 611 & 559 & 583 & 578 & 586 & 547 & 590 & 561 \\ 569 & 534 & 613 & 537 & 556 & 592 & 589 & 578 \\ 582 & 594 & 579 & 552 & 576 & 554 & 555 & 532\end{matrix} ]$$

Embodiments of the disclosed technology provide a joint hardware and firmware design, as described above, that mitigates uneven NAND wearing out. The multi-bit inversion seed is determined based on the PEC for each page type, and implemented in firmware. Flip sequences are also designed for each page type, and the data inversion (or randomization) operation is configured based on the inversion seed and the flip sequence for that particular page type. Since only XOR operations and circular shifts are needed to implement the described procedures, they can be performed much faster than any software-based implementation.

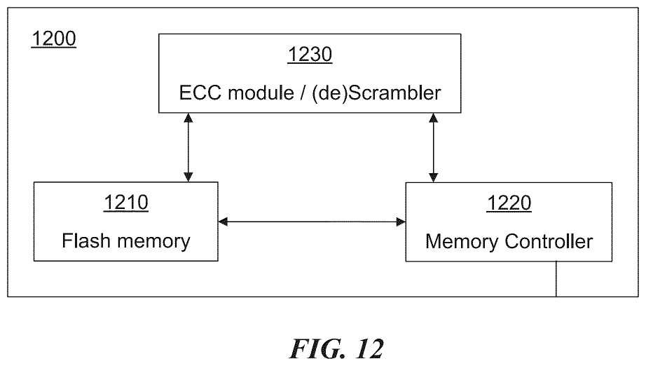

FIG. 11 illustrates a flowchart of an example method 1100 for improving the performance of a memory device. The method 1100 includes, at operation 1110, generating, based on a number of program erase cycles of the non-volatile memory, an inversion seed for a page type of the non-volatile memory. In some embodiments, operation 1110 is performed by the firmware of a data-storage device (e.g., data storage device 1200 in FIG. 12). In some examples, the firmware is stored in a flash memory (e.g., flash memory 1210 in FIG. 12). In other examples, in the context of FIG. 12, the firmware is stored on a non-volatile memory that is different from flash memory 1210, but within the data storage device 1200.

The method 1100 includes, at operation 1120, generating a circular shift flip sequence based on the inversion seed and a flip sequence, and at operation 1130, performing a bit-flipping operation on an input bit sequence based on the circular shift flip sequence to generate an intermediate bit sequence. In some embodiments, operations 1120 and 1130 are performed in a system-on-chip (SoC) of a data-storage device (e.g., data storage device 1200 in FIG. 12). In some examples, the SoC is implemented on a memory controller (e.g., memory controller 1220 in FIG. 12). In other examples, in the context of FIG. 12, the SoC is implemented on a controller different from the memory controller 1220, but within the data storage device 1200.

The method 1100 includes, at operation 1140, processing the intermediate bit sequence to generate an output bit sequence, and at operation 1150, writing the output bit sequence to a page in the non-volatile memory. In this example, the page that the output bit sequence is written (or programmed) to is of the page type for which the inversion seed and circular shift flip sequence are generated. In some embodiments, operations 1140 and 1150 are performed by a memory controller of a data storage device (e.g., memory controller 1220 of data storage device 1200 in FIG. 12).

In some embodiments, processing the intermediate bit sequence includes encoding the intermediate bit sequence to generate an encoded bit sequence, and scrambling the encoded bit sequence to generate the output bit sequence. In some embodiments, the encoding and scrambling in performed by an encoder and randomizer, respectively. In some examples, the encoder and scrambler can be the implemented in ECC module/(de) Scrambler 1230 in FIG. 12.

In some embodiments, encoding the intermediate bit sequence comprises using a low-density parity check (LDPC) encoder.

In some embodiments, processing the intermediate bit sequence includes scrambling the intermediate bit sequence to generate a scrambled bit sequence, and encoding the scrambled bit sequence to generate the output bit sequence. In some embodiments, the encoding and scrambling in performed by an encoder and randomizer, respectively. In some examples, the encoder and scrambler can be the implemented in ECC module/(de) Scrambler 1230 in FIG. 12.

In some embodiments, the non-volatile memory is a triple-level cell (TLC) and the page type is a most significant bit (MSB) page type, a center significant bit (CSB) page type, or a least significant bit (LSB) page type.

In some embodiments, a length of the inversion seed is N bits, wherein a length of the flip sequence is 2^{N} bits, and wherein the number of program erase cycles of the non-volatile memory is denoted PEC. In some examples, the inversion seed is determined as (PEC % 2^{N}), where % represents a modulo operation. In other examples, the inversion seed is determined as ((PEC+PA) % 2^{N}), where PA is a physical address of the page.

In some embodiments, the input bit sequence comprises user data and firmware meta data, and wherein the inversion seed is embedded in the firmware meta data.

In some embodiments, the inversion seed, the flip sequence, and the circular shift flip sequence are identical for pages having a same page type.

FIG. 12 is an example diagram illustrating a storage device that can be configured to implement the described embodiments. Referring to FIG. 12, a data storage device 1200 may include a flash memory 1210, a memory controller 1220, and an error correction code (ECC) module and (de) scrambler 1230 (which is configured to perform ECC encoding and decoding, scrambling, and descrambling). The memory controller 1220 may control the flash memory 1210 and the ECC module and de (scrambler) 1230 in response to control signals input from the outside of the data storage device 1200. In the data storage device 1200, the flash memory 1210 may be configured the same or substantially the same as a non-volatile memory device. That is, the flash memory 1210 may read data from selected memory cells using different read voltages to output it to the memory controller 1220.

In some embodiments, firmware is stored in flash memory 1210. Alternatively, the firmware is stored on non-volatile memory that is different from flash memory 1210, but within the data storage device 1200. In some embodiments, the system-on-chip (SoC) is implemented on the memory controller 1220. In other embodiments, the SoC is implemented on a controller different from the memory controller 1220, but within the data storage device 1200.

In some embodiments, the data storage device 1200 may be a memory card device, an SSD device, a multimedia card device, an SD card, a memory stick device, an HDD device, a hybrid drive device, or an USB flash device. For example, the data storage device 1200 may be a card which satisfies the standard for user devices such as a digital camera, a personal computer, and so on.

Implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A method of improving a performance of a non-volatile memory, comprising:
generating, based on a number of program erase cycles of the non-volatile memory, an inversion seed for a page type of the non-volatile memory;
generating a circular shift flip sequence based on the inversion seed and a flip sequence;
performing a bit-flipping operation on an input bit sequence based on the circular shift flip sequence to generate an intermediate bit sequence;
processing the intermediate bit sequence to generate an output bit sequence; and
writing the output bit sequence to a page in the non-volatile memory, wherein the page is of the page type.

2. The method of claim 1, wherein processing the intermediate bit sequence comprises:
encoding the intermediate bit sequence to generate an encoded bit sequence; and
scrambling the encoded bit sequence to generate the output bit sequence.

3. The method of claim 2, wherein encoding the intermediate bit sequence comprises using a low-density parity check (LDPC) encoder.

4. The method of claim 1, wherein processing the intermediate bit sequence comprises:
scrambling the intermediate bit sequence to generate a scrambled bit sequence; and
encoding the scrambled bit sequence to generate the output bit sequence.

5. The method of claim 1, wherein the non-volatile memory is a triple-level cell (TLC) and the page type is a most significant bit (MSB) page type, a center significant bit (CSB) page type, or a least significant bit (LSB) page type.

6. The method of claim 1, wherein a length of the inversion seed is N bits, wherein a length of the flip sequence is 2^{N} bits, and wherein the number of program erase cycles of the non-volatile memory is denoted PEC.

7. The method of claim 6, wherein the inversion seed is determined as (PEC % 2^{N}), and wherein % represents a modulo operation.

8. The method of claim 6, wherein the inversion seed is determined as ((PEC+PA) % 2^{N}), wherein % represents a modulo operation, and wherein PA is a physical address of the page.

9. The method of claim 1, wherein the input bit sequence comprises user data and firmware meta data, and wherein the inversion seed is embedded in the firmware meta data.

10. The method of claim 1, wherein the inversion seed, the flip sequence, and the circular shift flip sequence are identical for pages having a same page type.

11. A system for improving a performance of a non-volatile memory, the system comprising:
a firmware configured to generate, based on a number of program erase cycles of the non-volatile memory, an inversion seed for a page type of the non-volatile memory;
a hardware controller configured to:
generate a circular shift flip sequence based on the inversion seed and a flip sequence, and
perform a bit-flipping operation on an input bit sequence based on the circular shift flip sequence to generate an intermediate bit sequence; and
a memory controller configured to:
process the intermediate bit sequence to generate an output bit sequence, and
write the output bit sequence to a page in the non-volatile memory, wherein the page is of the page type.

12. The system of claim 11, wherein the inversion seed, the flip sequence, and the circular shift flip sequence are identical for pages having a same page type.

13. The system of claim 11, wherein a length of the inversion seed is N bits, wherein a length of the flip sequence is 2^{N} bits, and wherein the number of program erase cycles of the non-volatile memory is denoted PEC.

14. The system of claim 13, wherein the inversion seed is determined as (PEC % 2^{N}), and wherein % represents a modulo operation.

15. The system of claim 13, wherein the inversion seed is determined as ((PEC+PA) % 2^{N}), wherein % represents a modulo operation, and wherein PA is a physical address of the page.

16. A non-transitory computer-readable storage medium having instructions stored thereupon for improving a performance of a non-volatile memory, the instructions, when executed by a processor, cause the processor to perform operations comprising:
generating, based on a number of program erase cycles of the non-volatile memory, an inversion seed for a page type of the non-volatile memory;
generating a circular shift flip sequence based on the inversion seed and a flip sequence;
performing a bit-flipping operation on an input bit sequence based on the circular shift flip sequence to generate an intermediate bit sequence;
processing the intermediate bit sequence to generate an output bit sequence; and
writing the output bit sequence to a page in the non-volatile memory, wherein the page is of the page type.

17. The non-transitory computer-readable storage medium of claim 16, wherein processing the intermediate bit sequence to generate the output bit sequence comprises:
encoding the intermediate bit sequence to generate an encoded bit sequence; and
scrambling the encoded bit sequence to generate the output bit sequence.

18. The non-transitory computer-readable storage medium of claim 16, wherein encoding the intermediate bit sequence comprises using a low-density parity check (LDPC) encoder.

19. The non-transitory computer-readable storage medium of claim 16, wherein processing the intermediate bit sequence to generate the output bit sequence comprises:
scrambling the intermediate bit sequence to generate a scrambled bit sequence; and
encoding the scrambled bit sequence to generate the output bit sequence.

20. The non-transitory computer-readable storage medium of claim 16, wherein the non-volatile memory is a triple-level cell (TLC) and the page type is a most significant bit (MSB) page type, a center significant bit (CSB) page type, or a least significant bit (LSB) page type.
